(19) United States
(12) Patent Application Publication
(10) Pub. No.: US 2005/0242876 A1
(43) Pub. Date: Nov. 3, 2005

(54) Parameter estimation method and apparatus

(76) Inventor: Frank Gerhard Ernst Obernosterer, Nurnberg (DE)

Correspondence Address: HARNESS, DICKEY & PIERCE, P.L.C., P.O. Box 8910, Reston, VA, 20195, US

(21) Appl. No.: 10/832,999

(22) Filed: Apr. 28, 2004

(51) Int. Cl. H03F 1/26

(52) U.S. Cl. 330/149

(57) ABSTRACT

A power amplifier predistortion method involves generating a reverse model of a power amplifier block. The reverse model is based on modeled output signal values of the power amplifier block and sampled output signal values of the power amplifier block.

### BACKGROUND OF THE INVENTION

1. Field of the Invention

The present invention relates in general to predistortion linearization techniques on power amplifiers, and more particularly to a device and method to estimate parameters for predistorting an input signal of a radio frequency (“RF”) power amplifier to compensate for nonlinearities introduced by the RF power amplifier.

2. Description of Related Art

RF power amplifiers are widely used to transmit signals in communication systems. Ideally, the power amplifier would provide a uniform gain throughout a dynamic range so that the output signal of the amplifier is a correct, amplified version of an input signal. In reality, however, power amplifiers do not exhibit perfect linearity; i.e., they introduce distortion (e.g., non-linear amplitude distortion and non-linear phase distortion). The distortion may appear within the bandwidth of the signal, and may also extend outside the bandwidth originally occupied by the signal. The out-of-band spectral artifacts may include, for example, spectrum distortions, splatters, and spectrum spreading.

The distortion introduced by the power amplifier may deteriorate the performance of the communication system. Linearization techniques have therefore been implemented. One common linearization technique is referred to as predistortion.

Predistortion techniques may employ a processing unit (or “predistorter”) that is inserted in a signal path in front of the power amplifier. The predistorter compensates for the amplifier's nonlinearity by modifying the power amplifier input signal. More specifically, the predistorter may apply a non-linear function to the input signal. The non-linear function may be an inverse of the amplifier's non-linear transfer characteristic. In this way, the power amplifier input signal may be predistorted in a manner that is equal to and opposite from the distortion introduced during amplification, so that the amplified signal appears undistorted.

Conventional predistortion techniques may be classified according to (1) the format of the signal being predistorted (i.e., an analog signal versus a digital signal), and (2) the predistortion parameter type (i.e., fixed parameters versus adaptive parameters). With respect to signal format, if the predistorter is operating with a digital input signal and a digital output signal, then the technique is denoted as “digital predistortion.” The second classification mentioned above relates to whether the predistorter implements a fixed non-linear function (which may have fixed predistortion parameters) or whether the predistorter's parameters are adjusted adaptively to potentially time variant properties of the power amplifier. Predistortion techniques involving adaptively adjusted predistortion parameters are generally thought to provide better results in terms of extending the range of power levels for which linearization can be achieved.

Although conventional predistortion techniques are generally thought to be acceptable, they are not without shortcomings. For example, adaptive predistortion techniques carried out in a digital format utilize feedback receivers to adaptively adjust the predistortion parameters. The feedback receiver has an analog-to-digital converter (“ADC”). According to convention, the ADC must have a sampling rate at least as great as the sampling rate of the digital predistortion realtime processing performed by the predistorter. ADC's having high sampling rates may be very expensive. Furthermore, for some communication systems, the required sampling rate of the ADC is close to today's technological limit.

### SUMMARY OF THE INVENTION

In an exemplary embodiment of the present invention, a power amplifier predistortion system may include a predistorter that distorts input signal values to produce output signal values at a first sample rate. The system may also include a power amplifier block having an amplification chain that amplifies the output signal values of the predistorter to produce an amplified signal, and a feedback receiver that samples the amplified signal at a second sample rate to produce sampled output signal values. A forward modeler models the power amplifier block in a forward direction to produce modeled output signal values. A parameter estimator updates parameters of the predistorter based on the sampled output signal values from the feedback receiver and the modeled output signal values from the forward modeler. The amplification chain may include a digital-to-analog converter, a modulator, and a power amplifier. And the feedback receiver may include a demodulator and an analog-to-digital converter.

In another exemplary embodiment of the present invention, a model of a power amplifier block is generated based on modeled output signal values of the power amplifier block and sampled output signal values of the power amplifier block. The generated model may be in the reverse direction, which is counter to the physical propagation direction of the transmit signal. The modeled output signal values may be determined from a forward model of the power amplifier block. The parameters of the forward model may be based on input signal values of the power amplifier block and the sampled output signal values of the power amplifier block. Parameters of a distortion function may be based on the generated reverse model. And an input signal to the power amplifier block is distorted based on the distortion function.

### BRIEF DESCRIPTION OF THE DRAWINGS

The present invention will become more fully understood from the detailed description below and the accompanying drawings, wherein like elements are represented by like reference numerals, which are given by way of illustration only and thus are not limiting of the present invention and wherein:

FIG. 1 is a schematic illustration of a power amplifier predistortion system according to an exemplary embodiment of the present invention;

FIG. 2 is a schematic illustration of a power amplifier predistortion technique performed by the system depicted in FIG. 1;

FIG. 3 is a schematic illustration of a power amplifier predistortion system according to the prior art; and

FIG. 4 is a schematic illustration of a power amplifier predistortion technique performed by the system depicted in FIG. 3.

### DETAILED DESCRIPTION OF EMBODIMENTS

To facilitate understanding of the present invention, the following description is presented in the following two sections. Section I discusses an adaptive, digital predistortion system and method according to convention. Section II discusses an adaptive, digital predistortion system and method according to an exemplary, non-limiting embodiment of the present invention.

Sections I and II discuss adaptive, digital predistortion techniques as applied to a digital complex valued baseband signal. Those skilled in the art will appreciate, however, that the same principles can be straightforwardly extended to predistortion of other signals, such as a digital intermediate frequency (“IF”) signal for example.

I.—Conventional, Adaptive, Digital Predistortion:

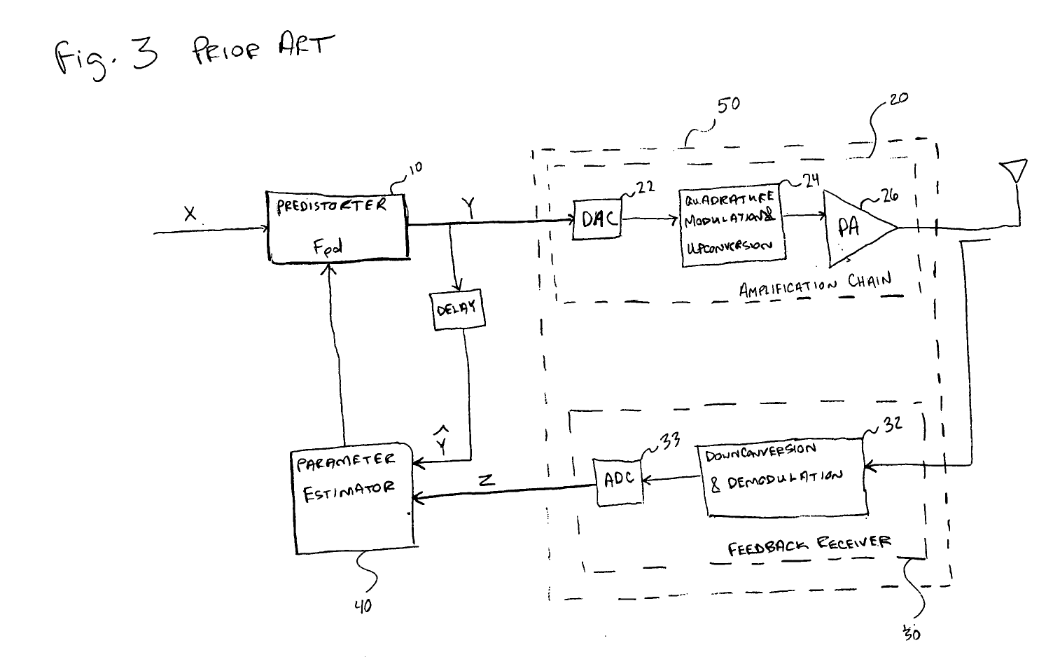

A conventional structure of an adaptive digital baseband predistortion system is schematically depicted in FIG. 3. The system includes a predistorter 10, an amplification chain 20, a feedback receiver 30, and a parameter estimator 40.

An input signal X is provided to the predistorter 10. The input signal X consists of a sequence of digital samples xₙ. The predistorter 10 maps the sequence of digital input samples xₙ to a predistorted output signal Y. The predistorted signal Y consists of digital samples yₙ.

A general transfer function F_{pd} of the predistorter 10 can be written as
Y=F_{pd}(X,\vec{p}) (1)
where \vec{p} is a parameter vector consisting of M parameters, pₘ, mε{1, . . . ,M}. The number M can be adjusted in a suitable way, as is well known in this art.

The predistorted digital baseband signal Y is fed into the amplification chain 20, inclusive of a digital-to-analog converter (“DAC”) 22, a quadrature modulation & upconversion module 24, and a power amplifier 26. More specifically, the predistorted digital signal Y is fed into the DAC 22. The converted signal is then fed into the quadrature modulation & upconversion module 24 to upconvert the signal to RF. The upconverted signal is then fed into the power amplifier 26. The amplification chain 20 may include additional non-linear amplifiers and/or other types of analog circuits.

After the power amplifier 26, a portion of the transmit signal is coupled out and input to the feedback receiver 30, inclusive of a downconversion & demodulation module 32 and an ADC 33. The coupled out portion of the transmit signal is downconverted and demodulated by the downconversion & demodulation module 32, and then converted into a digital format by the ADC 33. The ADC 33 outputs a digital waveform Z, which consists of the elements zₙ. The feedback receiver 30 may include additional and/or other types of analog circuits.

An Ideal Scenario:

For ease of explanation and to facilitate understanding, assume an ideal scenario in which the amplification chain 20 and the feedback receiver 30 are noise-free and exhibit ideal operating characteristics. That is, in the ideal scenario, the power amplifier 26 is noise-free and exhibits perfect linearity, and the peripheral components (inclusive of the DAC 22, the modules 24, 32, and the ADC 33) also exhibit ideal operating characteristics. By assuming the ideal scenario, the feedback receiver output signal Z may be described by the equation
Z=G·Ŷ, (2)
where Ŷ is a properly delayed version of the predistorted input signal Y, and where G is a complex valued gain factor which relates to the gain and phase shift of the power amplifier 26. The delay is necessary to compensate for the round trip delay of the signal Y through the amplification chain 20 and the feedback receiver 30.

For ease of explanation and understanding, and without loss of generality, assume that G=1.

Bi-Directional Transfer Functions:

In the following description, and consistent with convention, the term “forward direction” refers to the physical propagation direction of the signal through the system, and the term “reverse direction” refers to a direction that is counter to the physical propagation direction of the signal through the system.

Also, for ease of explanation and understanding, the amplification chain 20 and the feedback receiver 30 may be considered together as a power amplifier block 50. According to this conceptual framework, the predistorted signal Y is input to the power amplifier block 50, and the feedback receiver output signal Z is output from the power amplifier block 50.

A transfer function F_{PA}^{Y→Z} of the power amplifier block 50 in the forward direction from the predistorted signal Y to the feedback receiver output signal Z may be defined according to
Z=F_{PA}^{Y→Z}(Y,\vec{s}_{PA}^{fwd}), (3)
where \vec{s}_{PA}^{fwd} is a parameter vector, which is usually time variant, that is related to the current state of the power amplifier block 50.

A virtual transfer function F_{PA}^{Z→Y} of the power amplifier block 50 in a reverse direction from the feedback receiver output signal Z to the predistorted signal Y may be defined according to
Y=F_{PA}^{Z→Y}(Z,\vec{s}_{PA}^{rev}), (4)
where \vec{s}_{PA}^{rev} is the corresponding parameter state vector which describes the state of the power amplifier block 50 in reverse mode. Usually (but not in all cases), the transfer function F_{PA}^{Y→Z} in the forward direction is different than the transfer function F_{PA}^{Z→Y} in the reverse direction.

Assume that the delay is close to 0 (so that Ŷ=Y). For the ideal predistorter the objective is that the feedback receiver output signal Z, which represents the amplifier output signal, is identical to the input signal X (i.e., Z=X). Given the above assumptions, the equations (1) Y=F_{pd}(X, \vec{p}) and (4) Y=F_{PA}^{Z→Y}(Z,\vec{s}_{PA}^{rev}) may be solved to obtain the following ideal predistortion transfer function:
F_{pd}(X,\vec{p})=F_{PA}^{Z→Y}(X,\vec{s}_{PA}^{rev}). (5)
This means that an ideal predistortion function has a transfer function, which is identical to the transfer function of the power amplifier block 50 in the reverse direction. It is to be appreciated that the term “reverse direction” does not relate to a physical operation in the reverse direction, but instead indicates that the transfer function is defined from the feedback receiver output signal Z to the predistorted signal Y in a mathematical sense.

The Predistorter and Memory Effects Functionality:

According to convention, the predistorter may have a functionality to consider memory effects associated with the power amplifier. As is well known in this art, memory effects functionality provides more precise linearization as compared to that provided via a predistorter having memoryless functionality.

To achieve memory effects functionality, the predistorter 10 determines the output sample yₙ based on the related input sample xₙ and the preceding input samples xₙ₋₁, xₙ₋₂, xₙ₋₃, . . . . Put differently,
yₙ=ƒ(xₙ, xₙ₋₁, xₙ₋₂, . . . , x_{n-K},\vec{p}). (6)
In equation (6) above, the operator ƒ(.) in general represents a suitable, usually non-linear function. The variable K denotes the number of preceding input samples taken into account in addition to the current input sample. And the vector \vec{p}=(p₁, p₂, . . . , p_{M})^{T} is the predistorter parameter vector with M elements.

By way of example only, a predistorter transfer function ƒ (with M=5 and K=2) may be written as
yₙ=ƒ(xₙ, xₙ₋₁, xₙ₋₂, . . . , x_{n-K},\vec{p})=p₁xₙ+p₂xₙ₋₁+p₃xₙ₋₂+p₄xₙ|xₙ|²+p₅xₙ₋₁|xₙ₋₁|². (7)
Various and alternative predistorter transfer functions are well known in the art.

Parameter Estimation:

Once the predistorter transfer function is defined in a suitable way (as is well known in this art), the parameters of the parameter vector \vec{p}=(p₁, p₂, . . . , p_{M})^{T} may be defined. According to equation (5), and according to conventional wisdom, the predistorter parameter vector may be derived by estimating the transfer function of the power amplifier block 50 in the reverse direction. That is, so that the parameter estimation task is equivalent to computing the state vector \vec{s}_{PA}^{rev} of the power amplifier block 50 in the reverse direction based on the selected transfer function of the predistorter. The state vector \vec{s}_{PA}^{rev} may be computed using the predistorted signal Y and the output signal Z. Thus, as is well known in this art, the state vector (and therefore the predistorter parameter vector) may be estimated using a least squares (“LS”) approach, for example.

According to the conventional LS method, the following set of equations may be derived for parameter estimation. It will be appreciated that the following equations are based on the exemplary predistorter transfer function described by equation (7) above.
y_{N}=p₁z_{N}+p₂z_{N-1}+p₃z_{N-2}+p₄z_{N}|z_{N}|²+p₅z_{N-1}|z_{N-1}|². (9a)
y_{N-1}=p₁z_{N-1}+p₂z_{N-2}+p₃z_{N-3}+p₄z_{N-1}|z_{N-1}|²+p₅z_{N-2}|z_{N-2}|². (9b)
. . .
y_{N-L+1}=p₁z_{N-L+1}+p₂z_{N-L}+p₃z_{N-L-1}+p₄z_{N-L+1}|z_{N-L+1}|²+p₅z_{N-L}|z_{N-L}|². (9c)

The L equations (from (9) above) form a system of linear equations for the M parameters \vec{p}=(p₁, p₂, . . . , p_{M})^{T}. This may be written in matrix notation as:

$$\begin{matrix}Z \cdot {p}^{->} = {y}^{->} , with & ( 10 ) \\ {y}^{->} = {( {y}_{n} , {y}_{n - 1} , … , {y}_{n - L + 1} )}^{T} , and with & ( 11 ) \\ Z = ( \begin{matrix}{z}_{N} & {z}_{N - 1} & ⋯ & {\vert {z}_{N - 1} \vert}^{2} \\ {z}_{N - 1} & {z}_{N - 2} & ⋯ & {\vert {z}_{N - 2} \vert}^{2} \\ ⋯ & ⋯ & ⋯ & ⋯ \\ {z}_{N - L + 1} & {z}_{N - L} & ⋯ & {\vert {z}_{N - L} \vert}^{2}\end{matrix} ) & ( 12 )\end{matrix}$$

For L≧M, the solution of such an equation system is well known in the art.

It will be appreciated that for each of the above equations, at least K consecutive samples of the feedback receiver output signal Z are required. This means that the sampling rate for the output signal Z has to be at least as high as that of the predistorted input signal Y.

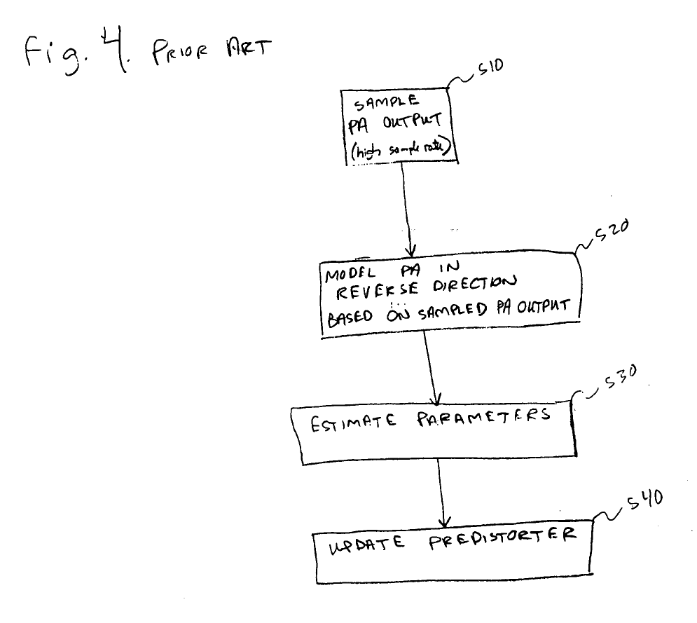

The conventional power amplifier predistortion system may estimate predistortion parameters as schematically shown in FIG. 4. Here, at step S10, the ADC 33 provides samples of the feedback receiver output signal Z. These samples, as discussed above, must be provided at a rate that is at least as high as the rate at which the predistorted input signal Y was provided by the predistorter 10.

The sampled output signal Z and the sampled delayed, predistorted input signal Ŷ are input to the parameter estimator 40. At step S20, based on the sampled signals Z and Ŷ, the parameter estimator 40 models the power amplifier block 50 in the reverse direction.

At step S30, the parameter estimator 40 estimates predistortion parameters based on the reverse model of the power amplifier block 50 obtained in the preceding step. And, at step S40, the parameter estimator 40 forwards updated predistortion parameters to the predistorter 10.

As discussed above, the conventional parameter estimation approach requires the baseband representation Z output from the power amplifier block 50 to be provided at a sampling rate that is at least as great as that of the input signal Y to the power amplifier block 50. As the predistorter 10 significantly expands the bandwidth of the input signal X due to its non-linear transfer function, the required sampling frequency for Y (or Ŷ) and therefore for Z is typically 3 to 5 times larger than the sampling frequency of the desired transmit signal X. This is problematic, especially in multicarrier wireless communication systems in which the required sampling rates for the ADC 33 of the feedback receiver 30 are close to technological limits and therefore rather expensive.

II.—Exemplary, Non-Limiting Embodiment of Adaptive, Digital Predistortion:

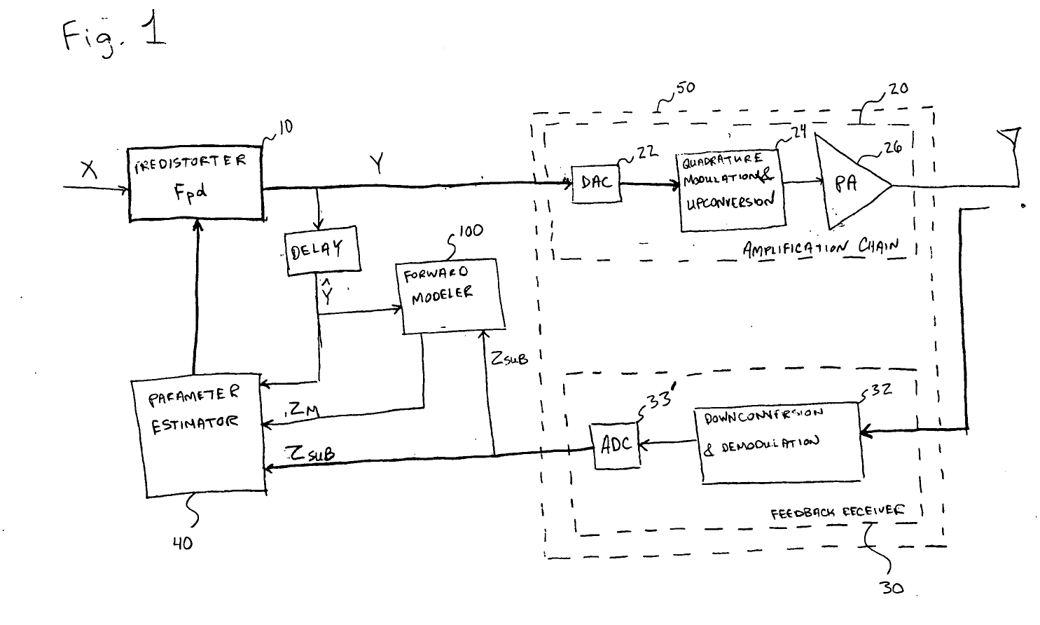

An adaptive digital baseband predistortion system according to an exemplary, non-limiting embodiment of the present invention is schematically depicted in FIG. 1. The system includes numerous components that are similar to those noted above with respect to the conventional predistortion system. The similar components have been designated with like reference numerals, and therefore a detailed description of the same is omitted.

In addition to the traditional components, the system depicted FIG. 1 includes a forward modeler 100 and an ADC 33′. The ADC 33′ may provide output signal values at a sample rate that is lower than the sample rate required of the ADC 33 implemented the conventional system depicted in FIG. 3. The lower sample rate feature is provided in part by the functionality of the forward modeler 100 and its interaction with the other components of the system, which will be described in detail below.

The basic approach of the system involves: (1) modeling the power amplifier block 50 in the forward direction (via the forward modeler 100); (2) applying sub-sampling to the output Z of the power amplifier block 50 (3) using the forward modeler 100 to reconstruct output values of the power amplifier block 50 that are missing due to sub-sampling; and (4) estimating the predistortion parameters based on both sampled output signal values and modeled output signal values.

The Forward Modeler:

The forward modeler 100, which models the power amplifier block 50 in the forward direction, generates modeled output signal values Z_{M} based on the predistorted input signal Y. The modeled output signal values Z_{M} substitute for sampled output signal values that are missing (at the parameter estimator 40) due to the application of sub-sampling. In this context, the term “missing” refers to those sample output signal values that are not explicitly provided by the ADC 33′ of the feedback receiver 30 due to applied sub-sampling. The modeled output signal values Z_{M} and the sub-sampled output signal values Z_{SUB} may be supplied to the parameter estimator 40. The parameter estimator 40 may then implement a conventional parameter estimation technique, for example, using the LS approach described in equation (9) above.

The forward modeler 100 may implement a suitable forward transfer function F_{PA}^{Y→Z} to model the power amplifier block 50 in the forward direction. The model parameters may be obtained based on the known predistorted input signal Y and the sub-sampled output signal values Z_{SUB}.

Once a suitable transfer function F_{PA}^{Y→Z}(Y,\vec{s}_{PA}^{fwd}) is defined, the related parameter state vector \vec{s}_{PA}^{fwd} of the power amplifier block 50 may be obtained by conventional parameter estimation techniques, such at the LS approach described in equations (9) above, for example.

Consider the following system of equations, which is presented as an example only and not as a limitation of the invention. The sample system has P equations (as noted below) that may be used to determine the state vector \vec{s}_{PA}^{fwd}=(s₁^{fwd}, s₂^{fwd}, . . . , s_{R}^{fwd})^{T}, where R is the number of parameters in the forward transfer function of the power amplifier block 50. For convenience only and not as a limitation of the invention, assume that the forward transfer function of the power amplifier block 50 has the same structure as the reverse transfer function discussed above with respect to convention. It will be appreciated, however, that the transfer function models for the forward and the reverse directions of the power amplifier block do not necessarily include the same terms.
z_{N}=s₁^{fwd}y_{N}+s₂^{fwd}y_{N-1}+s₃^{fwd}y_{N-2}+s₄^{fwd}y_{N}|y_{N}|²+s₅^{fwd}y_{N-1}|y_{N-1}|² (13a)
z_{N-1}=s₁^{fwd}y_{N-1}+s₂^{fwd}y_{N-2}+s₃^{fwd}y_{N-3}+s₄^{fwd}y_{N-1}|y_{N-1}|²+s₅^{fwd}y_{N-2}|y_{N-2}|² (13b)
. . .
z_{N-P+1}=s₁^{fwd}y_{N-P+1}+s₂^{fwd}y_{N-P}+s₃^{fwd}y_{N-P-1}+s₄^{fwd}y_{N-P+1}|y_{N-P+1}|²+s₅^{fwd}y_{N-P}|y_{N-P}|² (13c)

It will be appreciated that consecutive values of the predistorted input signal Y are required to solve the above equation system. Such consecutive signal values are readily available. Also, there is one dedicated equation for each output signal value zₙ. This means that the sequence of output signal values (z_{N}, z_{N-1}, z_{N-2}, . . . z_{N-L+1}), which forms the left side of the equation system, is necessary.

However, the above equation system may be modified so as not to require consecutive samples z_{N}, z_{N-1}, . . . of the output signal Z. The modification of the equation system will be appreciated with reference to the following example, which implements a sub-sampling factor of 2.

For a sub-sampling factor of 2, every other equation of the above equation system may be skipped. And to maintain the total number of equations (P), additional equations may be added as follows:

$$\begin{matrix}{z}_{N} \\ {z}_{N - 2} \\ {z}_{N - 4} \\ ⋯ \\ {z}_{N - 2 P + 2} \\ sampled \\ values\end{matrix} \begin{matrix} = {s}_{1}^{fwd} {y}_{N} + {s}_{2}^{fwd} {y}_{N - 1} + {s}_{3}^{fwd} {y}_{N - 2} + {s}_{4}^{fwd} {y}_{N} {\vert {y}_{N} \vert}^{2} + {s}_{5}^{fwd} {y}_{N - 1} {\vert {y}_{N - 1} \vert}^{2} \\ = {s}_{1}^{fwd} {y}_{N - 2} + {s}_{2}^{fwd} {y}_{N - 3} + {s}_{3}^{fwd} {y}_{N - 4} + {s}_{4}^{fwd} {y}_{N - 2} {\vert {y}_{N - 2} \vert}^{2} + {s}_{5}^{fwd} {y}_{N - 3} {\vert {y}_{N - 3} \vert}^{2} \\ = {s}_{1}^{fwd} {y}_{N - 4} + {s}_{2}^{fwd} {y}_{N - 5} + {s}_{3}^{fwd} {y}_{N - 6} + {s}_{4}^{fwd} {y}_{N - 4} {\vert {y}_{N - 4} \vert}^{2} + {s}_{5}^{fwd} {y}_{N - 5} {\vert {y}_{N - 5} \vert}^{2} \\ \\ = {s}_{1}^{fwd} {y}_{N - 2 P + 2} + {s}_{2}^{fwd} {y}_{N - 2 P + 1} + {s}_{3}^{fwd} {y}_{N - 2 P} + {s}_{4}^{fwd} {y}_{N - 2 P + 2} {\vert {y}_{N - 2 P + 2} \vert}^{2} + {s}_{5}^{fwd} {y}_{N - 2 P + 1} {\vert {y}_{N - 2 P + 1} \vert}^{2} \\ \\ \end{matrix} \begin{matrix}( 14 a ) \\ ( 14 b ) \\ ( 14 c ) \\ \\ ( 14 d ) \\ \\ \end{matrix}$$

It will be appreciated from the left side of the equations (14) that the P elements (z_{N}, z_{N-2}, z_{N-4}, . . . z_{N-2P+2}) are no longer in direct consecutive order, i.e., with single-spaced indices. Instead, only every other signal value zₙ is necessary to solve the modified equation system. By virtue of the modified equation system, the ADC 33′ in the feedback receiver 30 may apply sub-sampling by a factor of 2 for this specific example.

The desired parameter vector \vec{s}_{PA}^{fwd} may be obtained by solving the above equation system. This may be done using the conventional LS approach, for example.

After computing the parameter vector \vec{s}_{PA}^{fwd}, the forward transfer function of the power amplifier block 50 is known. The forward transfer function may be used to generate modeled output signal values Z_{M} for any considered input sequence (ŷ_{N}, ŷ_{N-1}, ŷ_{N-2}, . . . ).

Reconstruction of Missing Output Samples:

According to conventional wisdom, when parameter estimation is performed (e.g., according to the equation system (9)), the feedback receiver output signal Z must be sampled at a full sampling rate, i.e. consecutive sample values must be available. However, when a sub-sampling technique is applied for the output signal Z, the feedback receiver 30 need not provide every consecutive sample value. This is because those samples of the output signal Z that are not provided by the feedback receiver 30 may be generated by the forward modeler 100.

Further consider the scenario above that involves a sub-sampling factor of 2. Here, the even-indexed samples (z_{N}, z_{N-2}, z_{N-4}, . . . ) may be provided by the feedback receiver 30 and constitute the signal Z_{SUB} in FIG. 1. Thus, the missing, odd-indexed samples required for the equation system (9) would be (z_{N-1}, z_{N-3}, z_{N-5}, . . . ). These missing, odd-indexed samples, which constitute the signal Z_{M} in FIG. 1, may be modeled using the forward modeler 100, for which the parameters have been derived, according to the expression
zₙ=s₁^{fwd}yₙ+s₂^{fwd}yₙ₋₁+s₃^{fwd}yₙ₋₂+s₄^{fwd}yₙ|yₙ|²+s₅^{fwd}yₙ₋₁|yₙ₋₁|², nε{N−1, N−3, N−5, . . . }. (15)

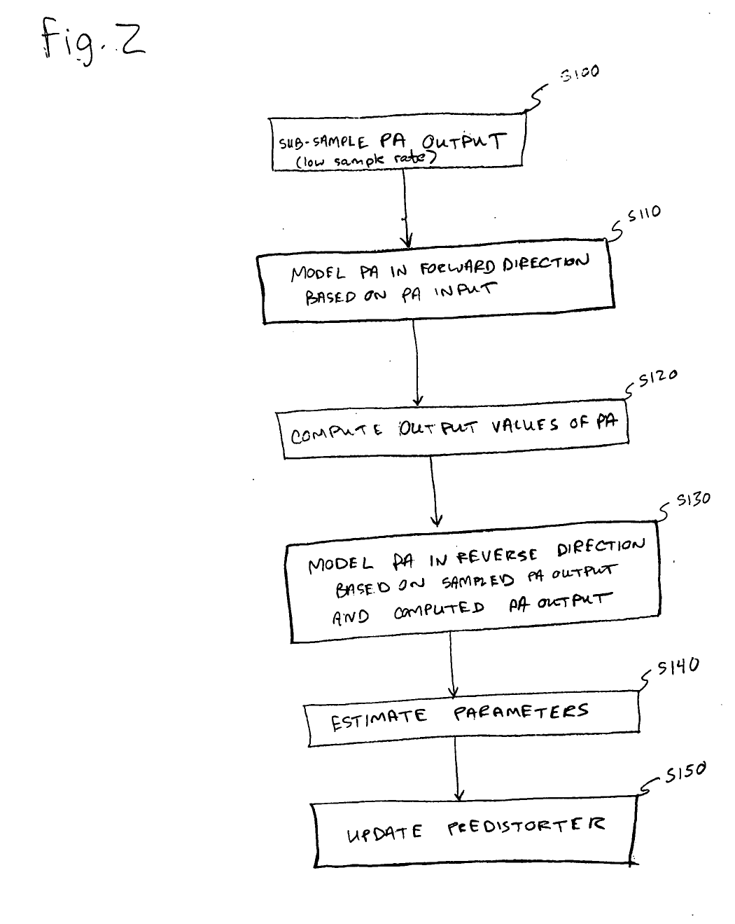

The power amplifier predistortion system may estimate predistortion parameters as schematically shown in FIG. 2. Here, at step S100, the ADC 33′ provides sub-samples Z_{SUB} of the feedback receiver output signal Z. The samples are characterized as “sub-samples” Z_{SUB} since they are provided at a rate that is less than that of the predistorted input signal Y provided by the predistorter 10.

The sub-sampled output signal values Z_{SUB} and the predistorted input signal Ŷ are input to the forward modeler 100. By virtue of using a modified equation system (e.g., the equation system (14) above), the two inputs Z_{SUB} and Ŷ may be used to obtain the desired parameter vector \vec{s}_{PA}^{fwd} so that the forward transfer function of the power amplifier block 50 is known. In this way, at step S10, the forward modeler 100 may model the power amplifier block 50 in the forward direction. At step S120, the forward modeler 100 generates (or computes) modeled output signal values Z_{M} for any considered input sequence (ŷ_{N}, ŷ_{N-1}, ŷ_{N-2}, . . . ).

The sub-sampled output signal values Z_{SUB}, the modeled output signal values Z_{M}, and the delayed, predistorted input signal Ŷ are input to the parameter estimator 40. At step S130, based on the three inputs Z_{SUB}, Z_{M}, and Ŷ, the parameter estimator 40 models the power amplifier block 50 in the reverse direction.

At step S140, the parameter estimator 40 estimates predistortion parameters based on the reverse model of the power amplifier block 50 obtained in the preceding step. And, at step S150, the parameter estimator 40 forwards updated predistortion parameters to the predistorter 10.

For ease of illustration and understanding, the exemplary embodiment of the invention has been described using a sample transfer function and a sub-sampling ratio of 2. However, those skilled in the art will appreciate that any suitable transfer function can be applied and sub-sampling factors other than 2 can be chosen.

Numerous features of the invention including various and novel details of construction, combinations of parts and method steps have been particularly described with reference to the accompanying drawings and pointed out in the claims. It will be understood that the particular predistortion system and method embodying the invention is shown by way of illustration only and not as a limitations of the invention. The principles and features of this invention may be employed in varied and numerous embodiments without departing from the scope of the invention.

1. A method comprising:
generating a model of a power amplifier block based on modeled output signal values of the power amplifier block and sampled output signal values of the power amplifier block.

2. The method of claim 1, further comprising:
determining the modeled output signal values from a forward model of the power amplifier block.

3. The method of claim 2, further comprising:
determining parameters of the forward model based on input signal values of the power amplifier block and the sampled output signal values of the power amplifier block.

4. The method of claim 2, wherein the generating step generates a model of the power amplifier block in a reverse direction.

5. The method of claim 1, wherein the generating step generates a model of the power amplifier block in a reverse direction.

6. The method of claim 1, further comprising:
estimating parameters of a predistorter using the model of the power amplifier block.

7. A predistortion method comprising:
generating a forward model of a power amplifier block;
generating a reverse model of the power amplifier block based on modeled output signal values from the forward model of the power amplifier block and sampled output signal values of the power amplifier block; and
estimating parameters of a distortion function based on the reverse model; and
distorting an input signal to the power amplifier block based on the distortion function.

8. The predistortion method of claim 7, further comprising:
determining parameters of the forward model based on input signal values of the power amplifier block and the sampled output signal values of the power amplifier block;
wherein the generating a forward model step generates the forward model based on the determined parameters.

9. A predistortion system comprising:
a predistorter that distorts input signal values to produce output signal values at a first sample rate;
a power amplifier block including
an amplification chain that amplifies the output signal values of the predistorter to produce an amplified signal, and
a feedback receiver that samples the amplified signal at a second sample rate to produce sampled output signal values;
a forward modeler that models the power amplifier block in a forward direction to produce modeled output signal values; and
a parameter estimator that updates parameters of the predistorter based on the sampled output signal values from the feedback receiver and the modeled output signal values from the forward modeler.

10. The predistortion system of claim 9, wherein the second sample rate is less than the first sample rate.

11. The predistortion system of claim 9, wherein the amplification chain includes a digital-to-analog converter, a modulator, and a power amplifier.

12. The predistortion system of claim 9, wherein the feedback receiver includes a demodulator and an analog-to-digital converter.
